(19) United States
(12) Patent Application Publication
(10) Pub. No.: US 2026/0350250 A1
(43) Pub. Date: Nov. 5, 2026

(54) ARTIFICIAL INTELLIGENCE FOR WELL PLACEMENT OPTIMIZATION

(71) Applicant: ORIGEN AI, Hoboken, NJ (US)

(72) Inventors: Ruben Rodriguez Torrado, Hoboken, NJ (US); Mehdi Shishehbor, Cupertino, CA (US); Alberto Pumar Jimenez, Jersey City, NJ (US)

(21) Appl. No.: 19/646,359

(22) Filed: Apr. 13, 2026

Related U.S. Application Data
(63) Continuation-in-part of application No. PCT/US24/51140, filed on Oct. 11, 2024.
(60) Provisional application No. 63/543,614, filed on Oct. 11, 2023.

(51) Int. Cl. G06F 30/13

(52) U.S. Cl. CPC G06F 30/13

(57) ABSTRACT

An apparatus for computing includes an input interface configured to receive a base reservoir simulation representative of a geological oil reservoir, and a processor. The processor is configured to cluster the reservoir into a plurality of sub-regions, generate, in a first optimization process, a candidate pool of well positions in the reservoir by screening and pruning a search space of possible well trajectories, each candidate well position being geologically plausible and satisfying one or more operational constraints; and optimize, in a second optimization process, the candidate pool of well positions to determine an optimized pool of wells that maximizes a dynamic variable of the reservoir. The apparatus further includes an output interface configured to output the optimized pool of wells to a user.

### CROSS-REFERENCE TO OTHER APPLICATIONS

This application is a continuation-in-part of PCT/US24/51140, filed on Oct. 11, 2024, which itself claims the benefit of U.S. Provisional Patent Application No. 63/543,614, filed on Oct. 11, 2023, for “ARTIFICIAL INTELLIGENCE FOR WELL PLACEMENT OPTIMIZATION,” the entire disclosure of each of which is hereby incorporated by reference.

### TECHNICAL FIELD

The present invention is directed to the application of artificial intelligence techniques to the optimal placement of oil wells in a reservoir. In particular, the present invention utilizes two-loop optimizations. A first one optimizes the definition of possible well locations from an initial screening, and a second loop optimization optimizes final locations from a given set of possible well locations.

### BACKGROUND OF THE INVENTION

Most of the world's easily developable crude oil and natural gas reservoirs have likely been discovered, and the annual volume of crude oil and natural gas discoveries is declining. The IEA forecasts global demand to be 3.2 million barrels per day higher in 2030 than in 2023. Although 50,000 crude oil and natural gas reservoirs have been discovered, only ten percent of these oil reservoirs have a material impact on global supply. Therefore, it is important for operators to optimize their field development plans, specifically where to locate wells in the reservoir to maximize production, optimize capital expenditure (CAPEX), and reduce operating expenses (OPEX). This responsibility involves multidisciplinary teams of reservoir engineers (RE) and geoscientists attempting to develop optimal reservoir models that place wells based on complicated, heterogeneous geological maps and systems that depend on physical equations to characterize the interaction of the rock and the fluids. Traditionally, this problem has been approached by manual updates of the model over multiple iterations, where REs locate the best wells based on their assembled knowledge and experience combined with forecasting tools to evaluate the solution. However, due to the vast space to explore and limited timeline to make investment decisions, these techniques present many limitations. For this reason, leveraging state-of-the-art computation hardware, algorithmic optimization and mathematical techniques can be used to solve this problem.

With respect to optimization of a field development plan (“FDP”) for a hydrocarbon reservoir, it should be noted that, in general, all optimization algorithms require a first stage where the search space needs to be explored globally. After this first exploration stage, the solution found is often incrementally improved until some optimization stopping criterion is satisfied. The selection of an optimization algorithm has a strong dependency on the type of problem to solve, the size of the search space (i.e., the number of variables to optimize), its robustness to introduce constraints of different types, and the search/exploration capabilities.

However, conventional optimization techniques for well placement present several common drawbacks:

First, optimizers depend on computationally expensive finite volume reservoir simulators, where a simulation for large models can take hours or days. Additionally, optimizers potentially need to call the reservoir simulator millions of times to reach a local/global optimum. The combination of these issues results in most optimizers being impractical for well placement, or, even if they can be used, the solution is often sub-optimal.

Second, to be useful for well placement optimization (“WPO”), an algorithm must be created that generates well locations that are geologically plausible, in other words, respecting all geological constraints such as, for example, drilling in a high productivity rock type. In other words, the optimization algorithms must provide solutions that drilling engineers and geoscientists consider realistic enough to be implemented directly in the reservoir. Many optimizations—although theoretical—are not realistic, because they do not respect geological constraints.

Finally, another challenge facing current optimization techniques is the management of realistic operational constraints such as minimum and maximum distances between wells, maximum injection rate, etc. From a mathematical point of view, these non-linear constraints are complicated to manage in the optimizer and affect the convergence of the problem. This is due mainly to multiple local optima, and computational intensity, described below.

Nonlinear constrained optimization in well placement is particularly difficult because realistic operational constraints produce a complex, non-convex optimization landscape. Under such conditions, conventional optimizers frequently fail to identify the best overall solution and instead converge to suboptimal local solutions.

The problem is further compounded by the computational cost of evaluating candidate field development plans, particularly where reservoir simulation is required. As the size and complexity of the reservoir model increase, the number of evaluations that can be practically performed becomes severely limited.

Accordingly, what is needed in the art is a robust and efficient methodology for optimizing field development plans, particularly well locations, while satisfying operational constraints and maximizing economic return.

### SUMMARY OF THE INVENTION

In embodiments, systems and methods for the optimization of field development plans, specifically for well locations in real reservoirs, are presented. In embodiments, a method includes two-loop optimization techniques. In a first loop, an optimization is performed from an initial screening to define possible well locations. In a second loop, final well locations are optimized from a given set of possible well locations, where a dynamic variable, such as, for example, Net Present Value (NPV), is maximized, and all operational constraints are respected.

### BRIEF DESCRIPTION OF THE DRAWINGS

FIG. 1 illustrates well trajectory parameterization, in accordance with various embodiments.

FIG. 2 illustrates projection of a solution into a feasible region, in accordance with various embodiments.

FIG. 3 is an example process flow chart for an example well optimization method, in accordance with various embodiments.

FIG. 4 is an example process flow chart for an example smart sampling sub-process, in accordance with various embodiments.

FIG. 5 is an example system diagram for surrogate modelling, in accordance with various embodiments.

FIG. 5A is an example process flow chart for training a deep neural network, in accordance with various embodiments.

FIG. 6 illustrates a block diagram of a computer device suitable for practicing the present disclosure, in accordance with various embodiments.

FIG. 7 illustrates an example computer-readable storage medium having instructions configured to implement software implementations of and/or practice various aspects of the present disclosure.

### DETAILED DESCRIPTION OF THE INVENTION

For reservoir engineers (RE), optimizing well locations is not an easy task. Due to the large number of variables to optimize (e.g. dozens of wells, duration of water and gas cycle), the number of possible scenarios could be greater than 10²⁴, which is even more than the number of stars in our galaxy. In addition, the RE has to wait hours—and sometimes days—to run a complex reservoir simulation for a single FDP scenario. After that, the RE has to analyze and manually determine the next scenario (which is not easy due to the complexity of the objective function to optimize) and follow this workflow until they reach a target deadline (e.g., six months).

Reservoir simulation in porous media is a sophisticated computational technique used to model and predict fluid flow behavior in subsurface reservoirs. It combines principles of physics, mathematics, and computer science to create digital representations of oil and gas reservoirs, allowing engineers to analyze and forecast fluid movement through porous rock formations over time. The process involves integrating geological, petrophysical, and fluid models into a dynamic simulation that solves complex flow equations based on Darcy's law and conservation principles. These simulations typically use finite difference methods to discretize the reservoir into a grid of cells, enabling detailed 3D modeling of fluid interactions. Reservoir simulators can be black-oil, compositional, or thermal, depending on the level of detail required in fluid behavior representation. This powerful tool is essential for optimizing FDPs, making informed operational decisions, predicting reservoir performance, and evaluating enhanced oil recovery techniques, ultimately improving resource extraction efficiency and reducing costs in the oil and gas industry.

The main idea is as follows. Imagine there are 100 possible well locations, and it is necessary to select 20 wells. The total number of possible combinations of the desired 20 wells is 5.359833704×10\hat{ }20. Additionally, due to reservoirs usually being highly heterogeneous, with significant variations in porosity and permeability, it is difficult to determine the optimal combination (considering interference between wells) without a reservoir simulator tool. Consequently, humans have to manually run scenarios, with each scenario taking minutes or hours. It is very challenging for humans to perform this optimization manually.

Usually, this conventional methodology is sub-optimal because the number of scenarios that the RE is able to evaluate is small, and the solutions are biased, which does not guarantee the improvement of the FDP iteration by iteration. For that reason, well location optimization is highly challenging to solve manually, and computational/mathematical techniques are necessary to address this problem.

Decision-making for production strategy has been addressed formally from a mathematical simulation-based optimization perspective [18].

For example, one paper applied optimization using Genetic Algorithms (GA) to China's Pubei oil field [19]. Another example optimized the Eileen West End Area in Greater Prudhoe Bay, operated by British Petroleum, using EOR techniques such as WAG [14], where the key parameters evaluated were injection volume, injection rate, WAG ratios, and WAG sequencing or WAG cycle number. Although the formulation for well location is relatively new, several optimization techniques can be adapted to solve the target problem. Nonetheless, it should be understood that, in general, all optimization algorithms require a first stage where the search space needs to be explored globally. After this first exploration stage, the solution found is often incrementally improved upon until some optimization stopping criterion is satisfied, such as maximum number of simulations, maximum computational time, or no improvement of the objective function. The selection of the algorithm has a strong dependency on the type of problem being solved, the size of the search space (i.e., the number of variables to optimize), its robustness to introduce constraints of different types, and search/exploration capabilities.

In what follows, it is proposed to solve these drawbacks with a new optimization workflow based on artificial intelligence. In embodiments, the workflow manages the drawbacks separately. First, a two-loop AI optimization workflow may be used, where the first workflow provides a list of realistic candidate well locations (which may include, for example, hundreds of wells), and the second, an optimization workflow optimizes the best possible locations given a well candidate and a range of target wells (e.g., dozens). Secondly, in embodiments, a new surrogate modeling technology may be used that enables running simulations orders of magnitude faster than traditional reservoir simulation techniques—while conserving the same level of accuracy. Finally, a new formulation may be used to manage complex and non-linear constraints in the AI optimizer algorithms.

### Methodology

Optimizing well locations from a simulation-based optimization perspective is very challenging due to the large number of possible well locations to study, potentially greater than 10²⁴ possible combinations, as well as the dependency on an expensive reservoir simulator that limits the number of possible scenarios that can be evaluated. In embodiments, these drawbacks may be resolved using two different workflows that run sequentially, as follows:

1. Optimization to obtain possible well locations (high-loop optimization). Usually, well optimization algorithms have to evaluate possible well locations that are known, based on the properties of the reservoir, to not provide good results. Thus, in embodiments, the original action spaces may be pruned to obtain a set of solutions that could be optimal, which may then be further explored in a fine optimization workflow. In embodiments, to carry out this initial screening, an optimization problem may be used that provides a set of well trajectories to optimize in a reservoir-simulation (low-loop) first optimization workflow.

2. Actual well location optimization (low-loop optimization). Once an initial well-trajectory candidate is generated, the goal is to then obtain the final optimal well-trajectory that maximizes a dynamic property, such as, for example, Net Present Value (NPV), or, for example, recovery factor or oil production. In embodiments, this problem may be formally addressed from a mathematical simulation-based optimization perspective. However, such a perspective depends on a highly time-consuming commercial reservoir simulator (such as, for example, INTERSECT, ECHELON, T-NAVIGATOR, or the like) that limits the exploration to a small number of scenarios. For this reason, in embodiments, surrogate modeling (described in detail below) may be implemented.

Surrogate modeling based on deep learning has been shown to yield incredible results, allowing reservoir simulations to be accelerated several orders of magnitude [13], [9]. However, known surrogate models present several limitations due to the fact that they are often not very accurate for the prediction of oil production, and they do not introduce physical elements. In this disclosure, this problem is solved by using a new deep learning architecture that is inspired by the physics of reservoir simulation, and which can also be trained based on the residual of the equation. It is noted that residuals in differential equations measure how well an approximate solution satisfies the original equation by quantifying the error when the approximation is substituted back into the equation.

In addition, in embodiments, the disclosed methodology may implement a mechanism to manage non-linear operational constraints, which is a key element in optimizing realistic field development plan scenarios.

Both workflows may become more challenging when introducing geological uncertainty. Reservoir simulations require input from geological models (e.g., maps of porosity, permeability, etc.). These maps are typically generated using geostatistics and limited input data, meaning that information from a small number of wells is used to interpolate a full geological model. Consequently, there is a set of equiprobable geological models that can capture the reservoir's behavior or reservoir uncertainty; in other words, all these models could represent the reality of the reservoir.

From a mathematical perspective for well location optimization, uncertainty is introduced by calculating the expected value of an objective function, such as, for example, Net Present Value (NPV). This expected value is computed by simulating every production strategy that our optimization algorithm evaluates for all possible realizations, and subsequently calculating the average. This technique is computationally intensive, inasmuch as running simulations for multiple realizations can be expensive, especially for complex reservoir models.

To address this drawback, in embodiments, a new algorithm is implemented that may be referred to as “smart sampling.” The idea behind smart sampling is to determine the smallest set of realizations that allows for a similar expected value of the objective function to be obtained compared to the full set of realizations representing the uncertainty of the geological model.

Each of the two workflows are described next.

### 1. Optimization to Obtain Possible Well Locations

The main objective of a first high-loop optimization is to carry out an initial screening to obtain a set of candidate wells that are both plausible and that respect operational constraints. It is noted that the high-loop optimization goals are to provide an initial list of optimal well positions as input data for the lower loop optimization, which is responsible for finding the final optimal well locations based on a reservoir-simulation optimization perspective.

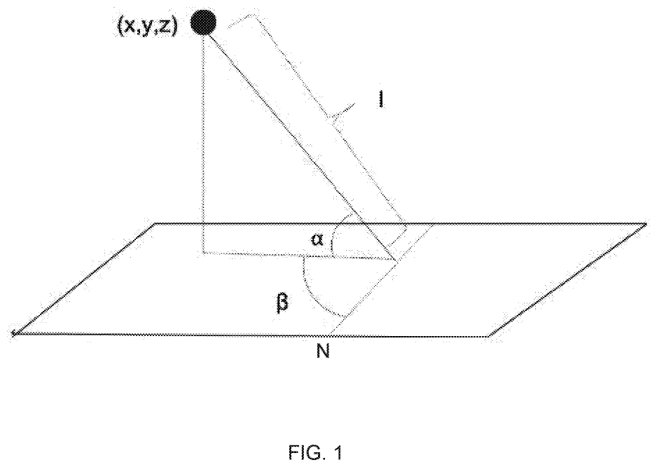

In embodiments, a first task is to automatically obtain a set of possible well-location trajectories. In embodiments, a well-location trajectory in 3D, y, may be parameterized using six different variables, y∈R⁶. These include three spatial coordinates for the initial position of the well (x, y, z), and then a well length, l, an elevation from the horizontal α, and an azimuth β (angle from true North), for the well, all as shown in FIG. 1.

However, such a formulation presents several limitations: First, a well trajectory in a reservoir simulator and/or surrogate must be provided in (i, j, k) cell coordinates, which are integer variables. Second, we need to transform this straight-line formulation into trajectories that follow the irregular shape of the layers that usually characterize a pillar gridding mesh. These challenges are approached using a new function φ: R⁶→l³, which may be used in embodiments to obtain \hat{ }y from y; \hat{ }y=φ(y). (For clarity, “\hat{ }y” is intended to be the standard “y with a hat over it”; however, due to typographical limitations, in this disclosure the hat generally precedes the variable, and the same usage occurs for a “y bar” variable, where the bar precedes the variable letter, as “ y”).

This function φ projects x in cell coordinates space into the cell coordinates grid and provides a realistic trajectory that is aligned with the pillar gridding mesh that was given.

Once a mathematical parametrization for a realistic well trajectory is obtained, in embodiments, the next task is to obtain an optimal set of candidate wells. In embodiments, this may be addressed from a mathematical optimization perspective. Here a geological/dynamic property may be maximized that provides a realistic and optimal screening for potential well candidates.

In embodiments, for example, the normalized opportunity index (“OI”) may be used as this property. An expression of this is found, for example, in [17]. The OI provides an initial value for the amount of oil, and the mobility ratio associated with a well trajectory. Therefore, in embodiments, the optimization problem may be formulated as:

$${Max}_{x , y , z , I , α , β} OI ( φ ( x , y , z , I , α , β ) ) \qquad Eq . ( 1 )$$

$$such that :$$

$$\underline{x} \leq x {\leq }^{—} x$$

$$\underline{y} \leq y {\leq }^{—} y$$

$$\underline{z} \leq z {\leq }^{—} z$$

$$\underline{I} \leq I {\leq }^{—} I$$

$$\underline{α} \leq α {\leq }^{—} α$$

$$\underline{β} \leq β {\leq }^{—} β ,$$

where the upper and lower limits for each variable are given based on reservoir knowledge, x, y, z, l, α, β∈R^{Nw,1} and Nw is the given number of wells. However, it is noted that this formulation could collapse into a single trajectory and provide a set of wells that has low variability. For this reason, in embodiments, the loss function may be modified, introducing a new term. This new term may, in embodiments, be composed of two different components: first, the distance between the different wells in \hat{ }y is calculated, dist(\hat{ }y)∈R^{Nw, Nw}, and subsequently the standard deviation of the upper triangular distance matrix is calculated. Finally, Equation (1) may be modified to read as follows, as Equation (2):

$${Max}_{x , y , z , I , α , β} λ 1 * OΙ ( φ ( x , y , z , I , α , β ) ) + λ2 * std ( {dist}^{UT} ( φ ( x , y , z , I , α , β ) ) )$$

$$such that :$$

$$\underline{x} \leq x {\leq }^{—} x$$

$$\underline{y} \leq y {\leq }^{—} y$$

$$\underline{z} \leq z {\leq }^{—} z$$

$$\underline{I} \leq I {\leq }^{—} I$$

$$\underline{α} \leq α {\leq }^{—} α$$

$$\underline{β} \leq β {\leq }^{—} β ,$$

where λ1 and λ2 are the weights of the objective function, OI is normalized by dividing by the total distance of the well, and std is normalized using the following equation

(std−stdₘᵢₙ)/(stdₘₐₓ−stdₘᵢₙ).

It is important to note that, in alternate embodiments, seismic attributes, for example, may be used instead of the OI. To do that, one replaces the OI in Equation (2) with the seismic attribute map, such as impedance.

However, in real fields the number of wells, lengths, azimuth, etc. may be different depending on the area of the reservoir, which may have different geological and/or petrophysical properties. To account for this, in embodiments, the optimization problem expressed in Equation (2) may be split into sub-optimization problems for each of these regions, obtaining the following Equation (3):

$${max}_{( xi , yi , zi , li , α i , β i )} \qquad Eq . ( 3 )$$

$$λ1 * OΙ ( φ ( {x}_{i} , {y}_{i} , {z}_{i} , {I}_{i} , {α}_{i} , {β}_{i} ) ) + λ2 + std ( {dist}^{UT} ( φ ( {x}_{i} , {y}_{i} , {z}_{i} , {I}_{i} , {α}_{i} , {β}_{i} ) ) ) ∀ i , i = 1 , … , Nc$$

$$such that :$$

$${\underline{x}}_{i} \leq {x}_{i} {\leq }^{—} {x}_{i} ∀ i = 1 , … , {N}_{c}$$

$${\underline{y}}_{i} \leq {y}_{i} {\leq }^{—} {y}_{i} ∀ i , i = 1 , … , {N}_{c}$$

$${\underline{z}}_{i} \leq {z}_{i} {\leq }^{—} {z}_{i} ∀ i , i = 1 , … , {N}_{c}$$

$${\underline{I}}_{i} \leq {I}_{i} {\leq }^{—} {I}_{i} ∀ i = 1 , … , {N}_{c}$$

$${\underline{α}}_{i} \leq {α}_{i} {\leq }^{—} {α}_{i} ∀ i , i = 1 , … , {N}_{c}$$

$${\underline{β}}_{i} \leq {β}_{i} {\leq }^{—} {β}_{i} ∀ i , i = 1 , … , {N}_{c}$$

where N_{c} is the cluster number, xᵢ, yᵢ, zᵢ, lᵢ, αᵢ, βᵢ∈R^{Nwi,1} and N_{wi} is the number of wells for the cluster i.

In addition, uncertainty could be introduced in this problem, replacing the value of the objective function in Equations (1), (2) and (3) with the expected value of the objective function, and calculating the expected value such as was described above.

NOTE: I do not see the calculation done]

In Equation (3), the concept of clustering is introduced. In general, the reservoir may be divided into a plurality of regions, or clusters, that exhibit similar geological behavior and/or are subject to similar operational constraints. By partitioning the reservoir into such sub-regions, the optimization problem may be addressed separately for each region, thereby allowing the well-placement strategy to better reflect local geological and operational characteristics.

In embodiments, different algorithms may be used to compute the clusters of the different sub-regions of the reservoir for Equation (3). For example, in some embodiments, k-means clustering may be used. K-means clustering is a method of vector quantization, coming originally from signal processing, that aims to partition n observations into k clusters, in which each observation belongs to the cluster with the nearest mean (cluster centers or cluster centroid), thereby serving as a prototype of the cluster [10]. In embodiments, x and y coordinates as well as depth may be used in order to calculate clustering with k-means. However, k-means can produce clustering with salt-and-pepper noise [1], which could be a drawback for the optimization problem of Equation (3). For that reason, in embodiments, post-processing such as median filters to remove this noise may be used. It is important to note that, alternatively, other post-processing techniques could be used, such as, for example, a pre-trained DNN that allows for the removal of noise [20].

Alternatively, other algorithms for clustering may also be used such as, for example, deep learning for image segmentation.

In embodiments, to determine if a cluster may be used as a possible area for well location, a tolerance tol may be defined. This tolerance may be compared with the average opportunity index for each cluster to determine if wells should be drilled in this area. Finally, Algorithm 1, provided below, provides a complete method for obtaining the initial set of optimal well locations. Moreover, it is noted that a derivative-free algorithm may preferably be used to solve the optimization problem of Equation (3). For example, the covariance matrix adaptation evolution strategy (CMA-ES) [6] algorithm may be used, which has shown high-quality results obtained in similar problems [12]. Additionally, the number of iterations necessary to solve CMA-ES is higher than 1 MM, and thus, in embodiments, high-performance computation (HPC) may preferably be used, as well as a thoroughly optimized implementation of the function φ.

Algorithm 1 - Algorithm to optimize possible well locations

```
Given a reservoir realization m;
Given number of clusters Nc;
Calculate 3D cluster C using k-means, C ← kmeans(m);
Given C, user provides constraints of Equation (3) as well as number of
wells per cluster, N_{wi};
Given tolerance C, tol
Given λ₁ and λ₂
x, y, z, α, β, l ← Ø
for i = 1 to N_{c} do
  if average(Cᵢ) > tol then
    Calculate xᵢ, yᵢ, zᵢ, αᵢ, βᵢ, lᵢ solving Equation (3) by CMA-ES
    x, y, z, α, β, l ← xᵢ, yᵢ, zᵢ, αᵢ, βᵢ, lᵢ
  end if
end for
```

### 2. Second Workflow: Optimization for Well Locations

In embodiments, the objective of the second workflow is, given a set of well trajectories defined by W∈R^{Nw= NP+ NI} and characterized by x, y, z, l, α, β, a subset of producers and injectors p, q⊂W is obtained such that a dynamic variable (e.g., NPV) is maximized. It is noted that in other embodiments, another objective function may be used, instead of NPV, as noted above. In embodiments, this problem may also be addressed from a mathematical simulation-based optimization perspective. In particular, the problem may be formulated using the following Equation (4):

$${max}_{p , q} NPV ( p , q )$$

$$such that :$$

$$\underline{{d}_{pp}} \leq d ( i , j ) \leq {{d}^{—}}_{pp} , ∀ i ∈ P , ∀ j ∈ P - \{ i \}$$

$$\underline{{d}_{ip}} \leq d ( i , j ) \leq {{d}^{—}}_{ip} , ∀ i ∈ I , ∀ j ∈ P$$

$$\underline{{d}_{ii}} \leq d ( i , j ) \leq {{d}^{—}}_{ii} , ∀ i ∈ I , ∀ j ∈ I - \{ i \}$$

$$sum ( x ) {\leq }^{—} N p - i ∀ i = 1 , … , {N}_{c}$$

$$sum ( x ) {\leq }^{—} N I - i ∀ i = 1 , … , {N}_{c}$$

where p∈{0, 1} ^{NP} is the binary vector for producer wells, and q∈{0, 1} NI is the binary vector for injector wells; d(.,.) is the Euclidean distance between two wells; N_{P} is the maximum number of producer wells to drill, and N_{I} is the maximum number of injectors to drill. In addition, I is the set of injector wells for a given y, and P is the set of producer wells for a given x. Finally, in embodiments, NPV may, for example, be calculated by:

NPV=SUM from t=1 to Nₜ[[Q_{0 to tn}(p,q)*Pₒ−N_{w}*P_{w}]/[(1+λ)^{tn/365}]*[Δtₙ]] Eq. (5)

(other calculations may also be utilized). Here, Qₒ indicates the field-wide oil production rate in stock tank barrels per day (STB/d), and N_{w} indicates the total number of wells drilled. Oil price, the cost to drill a well, and the annual discount rate are denoted by Pₒ, P_{w}, and λ respectively. The quantities tₙ and Δtₙ indicate time and the size of the time step in days, respectively.

One of the main challenges of this problem is to calculate Qₒ(p, q). Usually, Qₒ is calculated using a computationally expensive reservoir simulator. However, this poses an important drawback, as optimization techniques to efficiently solve Equation (4) require hundreds of thousands or millions of runs of the simulator, which is computationally prohibitive. In order to address this drawback, in embodiments, a new surrogate modeling approach based on deep learning may be used. This surrogate modeling approach can run simulations at a rate that is orders of magnitude faster than traditional simulators, but still obtain a similar level of accuracy for well rates as that of traditional simulators.

In embodiments, surrogate modeling offers a significant advantage with respect to traditional simulators, in that we can calculate the gradients or Jacobian matrix of the outputs (e.g., Qₒ) with respect to the input data (p, q) using automatic differentiation (AD) tools that are included in many machine learning libraries, such as, for example, PyTorch or TensorFlow. This allows one to use different gradient optimization algorithms, such as, for example, the Broyden-Fletcher-Goldfarb-Shanno algorithm (BFGS) to solve Equation (4).

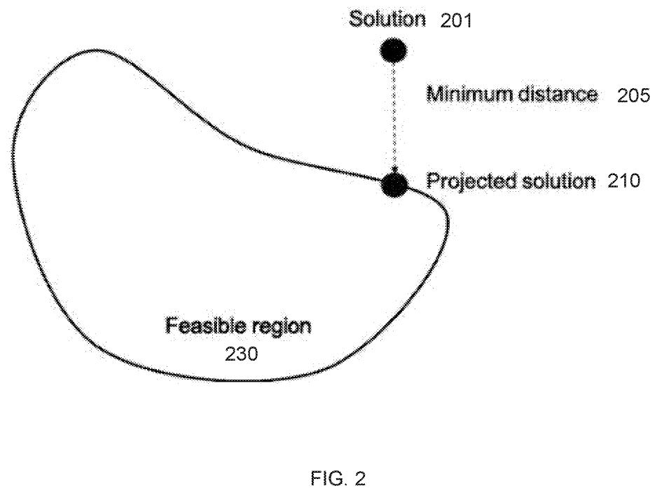

However, gradient optimization presents limitations in managing binary variables and non-linear constraints, as the derivative for binary variables can trap the optimization algorithm in local minima. Thus, in embodiments, for this specific formulation, derivative-free optimization may be used to solve Equation (4). To do this, CMA-ES may be used, in embodiments. However, one of the main challenges in CMA-ES optimization is the introduction of non-linear operational constraints that are found in Equation (4). Although it is possible to introduce penalty constraints or an augmented Lagrangian method ([3], [11]) here, this is challenging because the majority of the time the constrained term could direct the search in the optimization to suboptimal solutions. For that reason, in embodiments, a new operator for CMA-ES may be implemented that is applied after mutation and crossover. The main idea of such an operator is to project a solution that is infeasible (a solution that does not respect the constraints) to the closest feasible solution in a feasible region. This is illustrated, for example, in FIG. 2, where an infeasible solution 201 is projected into the feasible region 230, at a minimum distance. This results in projected solution 210, which is in the feasible region 230, and which is the closest solution to the infeasible solution 201 that satisfies or respects the constraints. Algorithm 2, provided below, illustrates how these projections may be carried out to respect the various distance constraints between two wells, in accordance with various embodiments. In general, these constraints are created or imposed by reservoir engineers or geoscientists.

Algorithm 2 Projection operator algorithm

```
Given a solution x
Given a feasible region characterized by the constraints of Equation (4)
for i ∈ D do
  for j ∈ D − {i} do
    if dₚₚ ≤ d(i, j) ≤ dₚₚ then
      Calculate the closest well to i that is feasible for ∀j ∈ D − {i}
    → r
      Replace i by r
    end if
  end for
end for
```

where D is the set of drilled wells D⊆W. The inventors have observed that the projection operator provides better solutions than the traditional penalty functions. Thus, traditional penalty functions are generally not recommended as the primary optimization technique due to several drawbacks. They may cause numerical instability by creating severe slope changes at constraint boundaries, making it difficult for algorithms to converge. Further, their effectiveness is highly sensitive to the choice of penalty parameter, often requiring an iterative approach that increases computational cost. Penalty methods also risk getting trapped in local extrema, necessitating multiple optimization runs from different starting points. Additionally, they may not be equally effective for all types of constraints. Due to these limitations, practitioners often prefer alternative approaches such as barrier methods, exact penalty methods, interior point methods, or Lagrangian methods, which may provide more stable and efficient optimization processes.

However, in embodiments, these drawbacks may be solved with the disclosed projection operator, as described above.

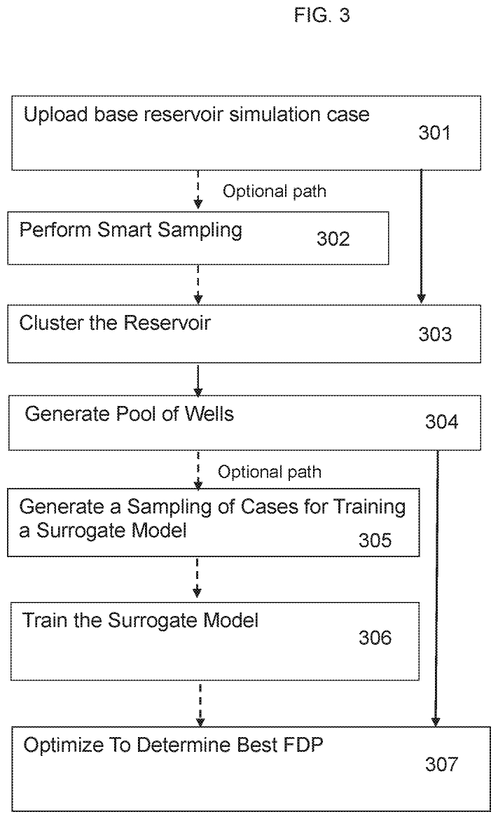

FIG. 3 is an example process flow chart for a method of optimizing an FDP, in accordance with various embodiments. With reference to FIG. 3, process flow begins at block 301, where a base reservoir simulation case is uploaded. This may be, for example, a single case, or, for example, a set of cases with different maps of porosity and permeability that characterize the geological uncertainty.

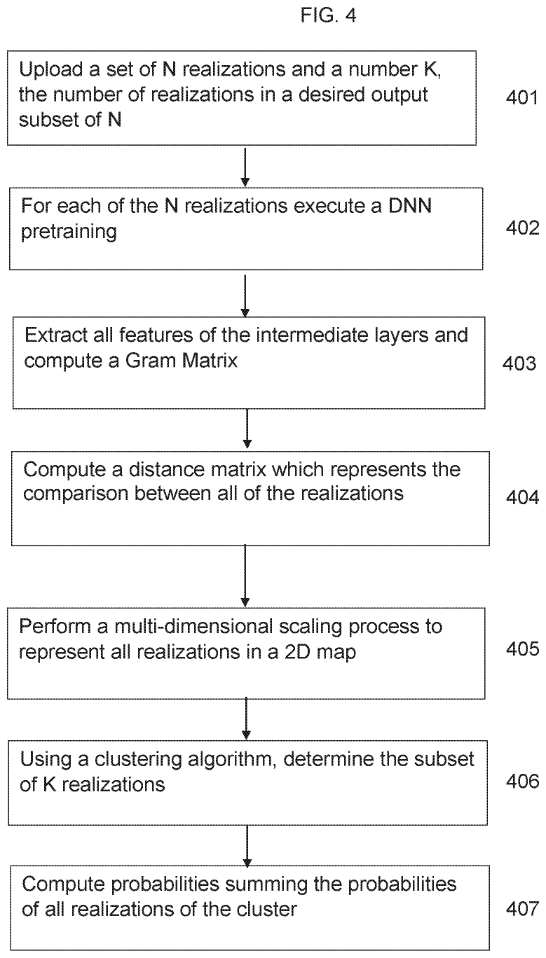

From block 301, process flow may optionally continue to block 302 or may skip block 302 and proceed directly to block 303. If the optional path to block 302 is chosen, then a smart sampling sub-process is performed. The objective of the smart sampling here is to obtain a subset of K realizations that provide identical or similar probability distributions to those of the N realizations, thus simplifying the computations. Details of this sub-process are described below with reference to FIG. 4.

From block 302, if that path is taken, process flow moves to block 303, where the reservoir is clustered. Alternatively, as noted, process flow may move directly from block 301 to block 303, and not perform smart sampling. Block 303 represents the first workflow described above, with reference to Equations (1), (2) and (3) and Algorithm 1. The output of this clustering operation is a pool of wells, generated at block 304.

From block 304, there is another optional choice. This is to either proceed to blocks 305 followed by block 306, to train a surrogate model, or to proceed directly to block 307 without surrogate model training. Block 307 involves the second workflow described above, with reference to Equations (4) and (5) and Algorithm 2.

If blocks 305 and 306 are not implemented, then instead of training a surrogate model, a reservoir simulator or other forecasting tool may be used, to predict oil/gas/water production/injection.

However, if surrogate training is used, then with reference to block 305, in embodiments, any sampling technique may be used to generate a sample of cases to train a surrogate model. For example, in some embodiments, Latin Hypercube Sampling (“LHS”) may be used to obtain the sample of cases. It is noted that the sampling must respect operational constraints such as, for example, minimum/maximum distance between wells, and/or maximum/minimum production or injection. In embodiments, what is sampled is, for example, well location.

In either option, process flow ends at block 307.

For the case where an exemplary embodiment performs smart sampling at block 302 of FIG. 3, then FIG. 4 is an example process flow chart for that smart sampling processing, in accordance with various embodiments. This sub-process is next described.

With reference to FIG. 4, process flow begins at block 401, where a set of N realizations of the reservoir is uploaded. The N realizations may be equiprobable, for example, or, alternatively, they may have different probabilities. Also at block 401, in addition, a number K, which is the desired number of realizations in a subset of N, is uploaded. As noted above, the objective here is to obtain a subset of K realizations that provide identical or similar probability distributions to those of the N realizations, thus simplifying the computations.

From block 401 process flow continues to block 402, where, for each of the N realizations, a DNN pretraining for image classification or other deep learning algorithm that allows feature extraction for images or 3D volumes is performed. The DNN may be, for example, C3D.

From block 402, process flow moves to block 403, where all features of the intermediate layers are extracted, and a Gram Matrix is computed. The input data may be, for example, sedimentological or petrophysical properties, or, for example, a combination of them, or even any other property that a user may decide to use.

From block 403, process flow moves to block 404, where a distance matrix is computed. The distance matrix represents a comparison between all of the N realizations. Thus, the principal diagonal of the distance matrix is equal to zero. From block 404, process flow moves to block 405, where a multi-dimensional scaling process is performed, using a multi-dimensional scaling algorithm to represent all of the N realizations in a 2D map. Alternatively, in other embodiments, another projection algorithm may be used here, such as, for example, t-SNE.

From block 405, process flow moves to block 406, where a clustering algorithm is used, such as, for example, K-means, to determine the subset of K realizations. K is a subset of the original N realizations.

Finally, from block 406, process flow moves to block 407, where probabilities are computed, summing the probabilities of all realizations of the cluster. In embodiments, the probabilities are calculated for the number of realizations in the cluster. For example, assuming N is equal to 10 and it is desired to ultimately have 3 clusters (K=3). The first cluster could have, for example, two realizations, the second cluster seven realizations and the last cluster one realization. Accordingly, in this example, the probability will be 20%, 70%, and 10%, respectively, for the first, second, and third clusters. This probability may then be used later to calculate the expected value, using:

Expected value=prob*NPV_realization

Process flow then ends at block 407.

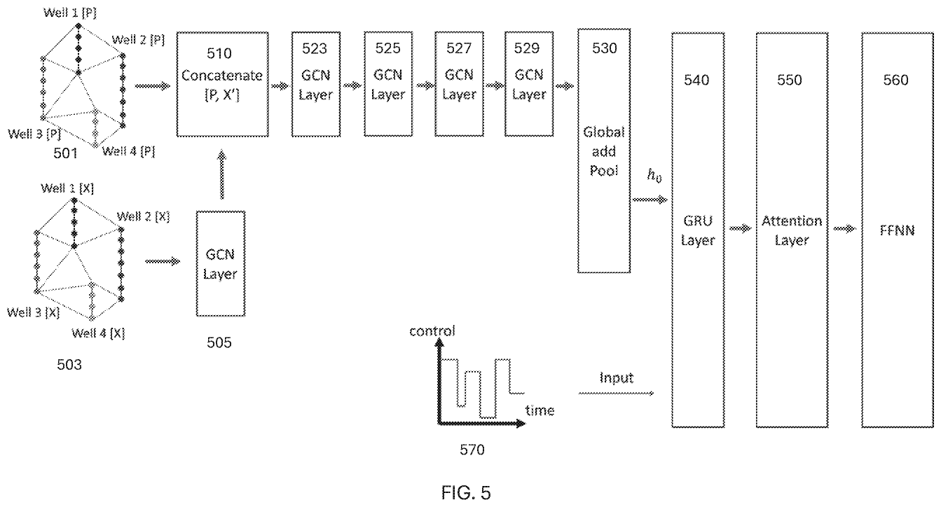

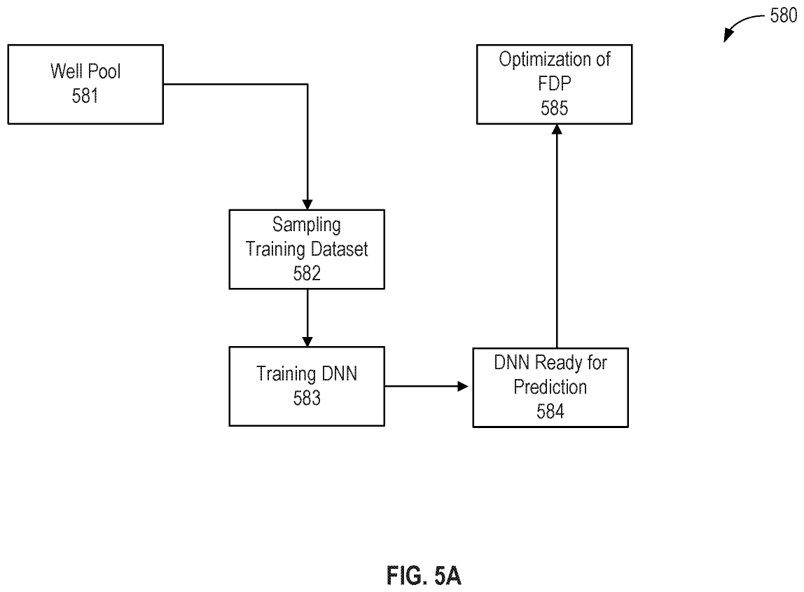

As noted above with reference to FIG. 3, blocks 305 and 306, in embodiments, a surrogate model may be trained to perform the optimization at block 307 of FIG. 3, to determine the best FDP. Details of surrogate modelling, in accordance with various embodiments, are next described. It is noted that FIG. 5 is an example architecture or system diagram for surrogate modelling, in accordance with such embodiments. Thus, in what follows, repeated reference will be made to the example architecture of FIG. 5 when describing the surrogate modelling methodology.

### Surrogate Modeling for Well-Based Reservoir Simulation

### 1. Overview

In embodiments, the disclosed optimization workflow further includes a surrogate model configured to forecast reservoir response for candidate field development plans (“FDPs”) without requiring a full reservoir simulation for each candidate. In embodiments, the surrogate model is particularly useful in the second workflow, where a large number of alternative well configurations may be evaluated under operational constraints. By replacing repeated high-cost simulator calls with a trained predictive model, the disclosed workflow may substantially reduce computational time while still preserving the information required for optimization.

Next described is a surrogate-model architecture according to various embodiments that jointly captures (i) spatial relationships among wells and their completions and (ii) temporal dependencies associated with well controls. As illustrated in FIG. 5, an example surrogate-model architecture may include a graph-based spatial encoder, a temporal sequence encoder, an attention mechanism, and a prediction head. More particularly, completion-based information 503 may be first processed by GCN layer 505, and the resulting completion representation that is output may then be concatenated at block 510 with petrophysical features. The petrophysical features are provided by the user and are typically obtained by applying one or more geostatistical techniques to input 501. The concatenated representation output from block 510 is then processed through a plurality of GCN layers 523, 525, 527, and 529 to generate a spatial latent representation of the wells and their completions. The resulting pooled representation 530 is used to initialize GRU layer 540 with hidden state h0_h_0h0, where h0h_0h0 is an internal latent state of the model derived from the pooled spatial representation and configured to provide an initial context for temporal sequence processing. GRU layer 540 also receives time-varying control input 570, which may include a sequence of well-control values over time, such as bottom-hole pressure, injection rate, producer constraints, or other operational settings. The GRU processes this temporal sequence to update its hidden states over successive time steps, thereby capturing temporal dependencies in the control history. The GRU outputs are then processed by attention layer 550, which assigns greater weight to the most informative temporal states so as to emphasize the time steps most relevant to the predicted production response. The output of attention layer 550 is then provided to feed-forward neural network (“FFNN”) 560, which maps the weighted temporal representation to one or more predicted production responses, thereby producing the final production forecast.

In embodiments, the input data to the surrogate model may include well locations, petrophysical properties, well completions in the form of reservoir cell coordinates (i, j, k), and one or more time-varying well controls, such as bottom-hole pressure, injection rate, or production constraints.

The output of the surrogate model may include time-series predictions of one or more production responses, such as oil, gas, and/or water production at the well level and/or the field level over a forecast horizon. In FIG. 5, the inputs used to generate such predictions include petrophysical information 501, completion-related information 503, and time-varying control input 570. These inputs are processed through concatenation block 510, GCN layers 523, 525, 527, and 529, global add pool 530, GRU layer 540, attention layer 550, and feed-forward neural network (“FFNN”) 560. The predicted production responses themselves are not separately illustrated as a labeled output block in FIG. 5, but are produced at the output of FFNN 560.

By way of example, the architecture shown in FIG. 5 may be viewed as a staged fusion architecture in which completion-related information, such as reservoir cell-coordinate completion data identifying locations at which wells are completed within a discretized reservoir grid, and petrophysical information, such as porosity, permeability, saturation-related properties, rock-type indicators, or combinations thereof, are not simply merged at the input. Instead, the completion-related information is first encoded through a graph module, for example GCN layer 505, to generate a completion-aware representation, and only thereafter fused with the petrophysical representation, for example by concatenation at block 510. This staged fusion, followed by temporal modeling at GRU layer 540 and attention-based weighting of the control history at attention layer 550, provides a compact latent representation that is particularly well suited to reservoir-production forecasting.

The details of the processing by the example architecture illustrated in FIG. 5 are provided in the discussion below in Section 4.

### 2. Generation of a Training Dataset for the Surrogate Model

A key element of the disclosed workflow is the generation of a training dataset that is simulated using a reservoir simulator to train the surrogate model. Preferably, the training dataset is generated so as to capture the boundaries of the operational space, thereby improving the learning efficiency of the surrogate model and enhancing its extrapolation capability. In embodiments, one or more design-of-experiments (“DOE”) techniques may be used for this purpose.

In some embodiments Latin Hypercube Sampling (“LHS”), which is one example of a DOE technique, may be employed to generate a representative set of training cases. LHS provides a structured approach for uniformly sampling the design space by partitioning each design dimension into equally probable intervals and selecting one sample from each interval. For a parameter vector X={x₁, x₂, . . . , xₖ), where the parameters may include, for example, distance-related design variables, one example of an LHS sample may be expressed as:

$${x}_{j}^{( i )} = {a}_{j} + [ ( i - 1 ) + ⋃ ( 0 , 1 ) ] / k ⋆ ( {b}_{j} - {a}_{j} ) ,$$

where aⱼ and bⱼ are the lower and upper bounds for parameter xⱼ, and U(0,1) is a uniform random variable.

A practical challenge in this context is that the DOE process should not merely sample the design space uniformly; it should also account for nonlinear operational constraints. In well-placement problems such constraints may include, for example, minimum and/or maximum allowable distances between wells, distinctions between producer-producer spacing, injector-injector spacing, injector-producer spacing, and other field-development rules which may be imposed by reservoir engineers or geoscientists. Accordingly, in embodiments, the disclosed dataset-generation process is constraint-aware and produces training samples that are consistent with physically and operationally feasible well configurations.

### 3. Constraint-Aware Sampling and Distance Constraints

In embodiments, the sampled well configurations may be generated subject to predefined real-world spacing constraints. Let the set of candidate wells be represented as:

W={w₁,w₂, . . . ,w_{N}}

where each well wᵢ has a set of associated spatial position, pᵢ:

pi=(xi,yi,zi).

Further, let P, an element of W, denote the set of producer wells, and let l, also an element of W, denote the set of injector wells.

In embodiments, the operational constraints may include three principal spacing categories: (1) distance between producers, Dₚₚ; (2) distance between injectors and producers, Dᵢₚ; and (3) distance between injectors, Dᵢᵢ.

For any two producers pᵢ, pⱼ, being elements of P, the producer-producer spacing may satisfy:

Dₚₚ(pᵢ,pⱼ)=∥pᵢ−pⱼ∥≥d^{pp}ₘᵢₙ

(this latter term means that d has both a subscript and a superscript, cannot conveniently write that in Word)

For any injector iₖ, an element of/and producer pⱼ, an element of P, the injector-producer spacing may satisfy:

Dᵢₚ(iₖ,pⱼ)=|pₖ−pⱼ∥≥d^{ip}ₘᵢₙ

For any two injectors iₖ, iₗ, elements of l, the injector-injector spacing may satisfy:

Dᵢᵢ(iₖ,iₗ)=∥iₖ−iₗ∥≥dⁱⁱₘᵢₙ

In some embodiments, injector-producer spacing may also be constrained above by a maximum allowable distance, such that:

d^{ip}ₘᵢₙ≤Dᵢₚ(iₖ,pⱼ)=∥pₖ−pⱼ∥≤d^{ip}ₘₐₓ

In embodiments, these spacing constraints may be selected based on both physical and operational considerations. For example, the minimum distance between producers may be chosen to reduce interference between production wells, while the injector-producer spacing may be selected to promote effective sweep and reduce premature breakthrough of injected fluids.

### 3.1 Iterative Replacement Process for Feasible Samples

In embodiments, each sampled configuration may be checked against the foregoing spacing constraints. If a sampled configuration violates one or more constraints, the configuration may be repaired through an iterative replacement process. In one example, the repair process may proceed as follows. First, the producer wells in the sampled configuration may be evaluated. If a producer well violates the applicable producer-producer spacing rule, that producer well may be replaced by another candidate producer well, outside the current sample, that satisfies the distance criteria relative to the remaining producer wells. Second, once the producer subset satisfies the applicable constraints, the injector wells may be evaluated. If an injector violates the applicable injector-producer and/or injector-injector spacing rule, that injector may be replaced by another candidate injector outside the current sample that satisfies the constraints. Third, the process may be repeated until a compliant well configuration is obtained.

The final compliant configuration may be denoted as W*. In this manner, the training dataset may preserve DOE coverage of the operational space while also respecting the nonlinear spacing constraints that characterize practical field-development scenarios.

### 4. Surrogate Model Architecture

### 4.1 General Architecture

In embodiments, a surrogate-model architecture configured to encode well-completion geometry, petrophysical context, and time-varying controls within a single predictive workflow may be implemented. In embodiments, the architecture may include: (i) a graph-based completion encoder, (ii) a graph-based spatial encoder for the fused well representation, (iii) a temporal encoder for well-control sequences, (iv) an attention mechanism configured to emphasize the most relevant temporal states or the importance of certain wells, and (v) a prediction head that outputs the production forecast. In FIG. 5, the attention mechanism may be implemented as attention layer 550. Thus, attention layer 550 is one example of a structure configured to perform the attention mechanism described herein. More particularly, attention layer 550 may receive outputs from GRU layer 540 and assign weights to different temporal states so as to emphasize those states that are most relevant to the predicted production response. In this manner, the attention mechanism described functionally herein corresponds, in the illustrated embodiment of FIG. 5, to attention layer 550. The architecture of FIG. 5 is next described with reference to its labeled blocks. As shown in the lower portion of FIG. 5, completion-related information X, which may include well-completion descriptors such as reservoir cell-coordinate completion data identifying locations at which wells are completed within a discretized reservoir model, is provided at 503 and processed by first GCN layer 505. As shown in the upper portion of FIG. 5, petrophysical information P for the wells, such as porosity, permeability, saturation-related properties, rock-type indicators, or combinations thereof, is then fused with the completion-derived representation at concatenation block 510, which is labeled “Concatenate [P, X]” in the figure. The fused spatial representation is then propagated through additional GCN layers 523, 525, 527, and 529, which progressively aggregate information from neighboring wells and related completions so as to generate a spatial latent representation reflecting both reservoir properties and well interactions. As further shown in FIG. 5, cont., the output of the spatial encoder is aggregated by global add pool 530, which combines the well-level latent features into a pooled spatial representation that summarizes the well configuration and encoded spatial context. This pooled spatial representation is then used to initialize the temporal module, for example by providing an initial hidden state for GRU layer 540. Control sequence 570 is also provided as an input to GRU layer 540 and may include a sequence of well-control values over time, such as bottom-hole pressure, injector rates, producer constraints, or other operational settings. GRU layer 540 processes this temporal sequence to capture temporal dependencies in the control history, and the GRU outputs are then processed by attention layer 550, which assigns greater weight to the temporal states most relevant to the predicted production response. The output of attention layer 550 is then provided to FFNN 560, which serves as a prediction head that maps the latent representation produced by the spatial and temporal encoders to one or more predicted production responses, such as a time-series forecast of oil, gas, and/or water production at the well level and/or the field level.

### 4.2 Input Representation and Graph Construction

In embodiments, the input to the model may be represented as a graph in which nodes correspond to wells and edges capture spatial and/or completion-related relationships between wells. The graph shown at the far left side of FIG. 5 is illustrative only, it being understood that the number of wells is certainly not limited to four, and the connectivity may be adapted to the reservoir model.

In embodiments, the node features may include, for example, petrophysical properties and completion-related descriptors. In some embodiments, the petrophysical properties may include porosity, permeability, saturation-related properties, rock-type indicators, or combinations thereof. The completion-related descriptors may include well completions expressed as reservoir grid indices (i, j, k). As used herein, a “completion” refers to a specific reservoir location at which the well is completed, and such a location may be described in terms of cell coordinates within a discretized reservoir model.

In embodiments, the completion information is not merely appended as a raw input feature. Rather, the completion-related representation X is first passed through GCN layer 505, thereby producing a completion-aware embedding, which is a learned latent representation that encodes spatial and structural information associated with the well completions and their relationships within the reservoir grid, before fusion with the petrophysical representation P.

This separation of completion aspects and petrophysical aspects is advantageous because completion geometry and petrophysical context carry different types of information. Completion geometry describes how the well interacts with the grid and reservoir layers, whereas petrophysical features describe the local reservoir properties.

By encoding the completion information first and then concatenating the resulting embedding with petrophysical features at block 510, the disclosed architecture preserves this distinction while allowing subsequent processing layers to jointly use both the completion-derived information and the petrophysical information to generate a combined latent representation for reservoir-production forecasting.

In embodiments, the graph connectivity may be constructed based on relationships among wells and, optionally, relationships among completions associated with the wells. For example, the connectivity may link wells to one another and may also link the top and bottom completions of a given well. The resulting graph therefore captures not only well-to-well spatial relationships, but also completion-related structure within the discretized reservoir.

### 4.3 Graph Convolutional Spatial Encoder

In embodiments, each GCN layer may transform the feature representation according to:

H^{(l+1)}=σ(A\hat{ }H^{(l)}W^{(l)},

Where H^{(l)} is the feature matrix at layer l, A\hat{ } is a normalized adjacency matrix representing the graph connectivity, W^{(l)} is a learnable weight matrix for the l-th layer, and σ is an activation function such as ReLU (Rectified Linear Unit, a popular activation function used in deep learning, defined as f(x)=max(0,x)). ReLU is used in hidden layers to introduce nonlinearity, allowing models to learn complex patterns, and its primary application is the default activation function in convolutional neural networks (CNNs). ReLU solves the vanishing gradient problem, enabling faster convergence compared to sigmoid or tanh functions. Because it sets negative inputs to zero, it produces sparse representations (many zeros), which makes computation more efficient.

As described above, in the example of FIG. 5, the fused well representation is processed through four GCN layers 523, 525, 527, and 529. These layers progressively aggregate information from neighboring wells and related completions, thereby producing a spatial latent representation, which is a learned internal representation that captures spatial structure, reservoir properties, and well-to-well interactions for use in subsequent production forecasting.

After the final GCN layer 529, the well-level latent features may be aggregated by global add pool 530. In embodiments, global add pool 530 combines the latent features corresponding to multiple wells into a single reservoir-level latent vector that summarizes the overall well configuration and encoded spatial context. By way of example, where each well is represented by a respective latent feature vector, global add pool 530 may sum the individual well-level vectors to generate a pooled vector representing the reservoir-level spatial state. This pooled representation may then be used to condition the temporal portion of the model, for example by providing an initial latent context for subsequent temporal processing.

### 4.4 Temporal Encoder and Attention Mechanism

Continuing with reference to FIG. 5, GRU layer 540 also receives time-varying control input 570. In embodiments, the control input may include a sequence of well controls over time, such as bottom-hole pressure, injector rates, producer constraints, or other operational settings. The temporal encoder is initialized with a hidden state derived from the pooled spatial representation. In the example of FIG. 5, this derivation may be performed by transforming the pooled output of global add pool 530, for example by a learned projection operation, into an initial hidden state suitable for GRU layer 540. In this manner, spatial information extracted from the well configuration and reservoir context is carried forward into the temporal encoder, thereby providing an initial latent context for processing the time-varying control sequence.

One example of such an initialization is:

h₀=ReLU(WₚᵣₒⱼH_{gcn}),

where Wₚᵣₒⱼ is a learnable projection matrix and H_{gcn} denotes the pooled output of the graph encoder.

In embodiments, the GRU layer may update its hidden state according to the following equations:

zₜ=σ(W_{z}xₜ+U_{z}hₜ₋₁+b_{z})

rₜ=σ(Wᵣxₜ+Uᵣhₜ₋₁+bᵣ)

h~ₜ=tanh(Wₕxₜ+Uₕ(rₜ⊙hₜ₋₁)+bₕ)

hₜ=(1−zₜ)⊙hₜ₋₁+zₜ⊙h~ₜ,

where
Where xₜ is the input at time step t and hₜ is the hidden state at time step t, and ⊙ is the Hadamard product (element-wise or entry-wise product of two matrices).

The GRU outputs may then be processed by attention layer 550. In embodiments, the attention layer is configured to assign greater weight to the most informative temporal states for the prediction task. One example of an attention formulation is:

Q=W_{q}h_{T}, K=Wₖh_{T}, V=Wᵥh_{T},

where W are learnable projection matrices used to transform the GRU output h into corresponding query, key, and value representations. In embodiments, these matrices are model parameters that are initialized, for example, with initial values and subsequently learned during training, for example through backpropagation and gradient-based optimization. The corresponding attention output may then be given by:

Attention(Q,K,V)=softmax(QK^{T}/√dₖ)*V,

Where dₖ is the key dimension, i.e., the number of features in each key representation. In embodiments, division by √dₖ scales the attention scores to improve numerical stability and maintain balanced weighting as the key dimension increases. In practical terms, the attention layer enables the model to focus on those time steps or control states that are most relevant to the predicted production response.

### 4.5 Prediction Head and Output

The output of attention layer 550 may be provided to FFNN 560, which forms the prediction head of the architecture. In one example, the prediction head may be expressed as:

y\hat{ }=W₃(ReLU(W₂(ReLU(W₁attention_output)

Where W₁, W₂ and W₃ are learnable matrices. In embodiments, these matrices are model parameters that are initialized, for example, with initial values and subsequently updated during training, for example through backpropagation and gradient-based optimization, so as to map the latent representation produced by attention layer 550 to the predicted production response.

In embodiments, the prediction head output y\hat{ } may include a time-series forecast of one or more production variables, such as oil production, gas production, water production, injection response, or combinations thereof, either at the individual well level, the field level, or both. The prediction head is not limited to a fully connected network. In other embodiments, other neural-network structures may be used in place of FFNN 560, provided that they map the latent representation produced by the spatial and temporal encoders to the desired production forecast.

### 4.6 Architectural Variants

Although FIG. 5 illustrates one example architecture, it is understood that the present disclosure is not limited to any specific number of graph layers, or the use of a GRU, the specific attention formulation, or the use of a feed-forward prediction head. In alternate embodiments, one or more of these components may be replaced by functionally similar modules. For example, the temporal encoder may include another recurrent architecture, such as, for example, a long short-term memory (“LSTM”) layer, or a temporal convolution module. Likewise, the attention mechanism may be replaced by another relevance-weighting or feature-selection mechanism, and the prediction head may include another neural-network structure suited to the target forecast.

### 5. Training and Use of the Surrogate Model in the FDP Workflow

In embodiments, the surrogate model may be trained using a supervised learning process in which the target values are obtained from reservoir-simulator runs generated from the sampled training dataset. The loss function may, for example, be a weighted mean absolute error (“MAE”) over the forecast horizon:

L=1/N*[Sum from i=1 to N[Sum from t=1 to D wt|y\hat{ }_{i,t}−y_{i,t|}]],

Where N is the number of training samples, D is the number of forecast time steps, wₜ is an optional time-step weight, y\hat{ }_{i,t} is the predicted response for sample i at time step t, and y_{i,t} is the corresponding simulator-derived response.

In embodiments, the loss function is not limited to weighted MAE. In alternate embodiments, other loss functions may be used, including mean squared error, Huber loss, composite losses, or loss functions augmented with regularization terms or constraint-aware terms.

In embodiments, the training process may be performed using an optimizer such as Adam, optionally together with a learning-rate scheduler. In embodiments, the scheduler may reduce the learning rate during training so as to improve convergence and facilitate fine tuning of the model parameters.

Algorithm 3 - Algorithm to Train Deep Neural Network (DNN)

```
Given a training dataset Dₜᵣₐᵢₙ;
Given user-defined parameters: number of epochs E and batch size B;
Initialize deep neural network model DNN with random weights;
Initialize optimizer (e.g., Adam) and loss function;
  for epoch e=1 to E do
    Shuffle the training dataset Dₜᵣₐᵢₙ;
    Divide Dₜᵣₐᵢₙ into batches of size B;
      for each batch b in Dₜᵣₐᵢₙ do
      Reset the gradients of the DNN;
      Perform forward pass to compute predicted output ŷ for the input
      batch b;
      Calculate loss L(y\hat{ },y) where y is the true output for batch b;
      Perform backpropagation to compute gradients with respect to the
      DNN weights;
      Update weights of the DNN using the optimizer;
      end for
  end for
```

### 5.1 Example Training Procedure Using Algorithm 3

An example training procedure for the surrogate model may be expressed as follows. First, a training dataset Dₜᵣₐᵢₙ is received. Second, user-defined training parameters are received, including a number of epochs E and a batch size B. Third, the surrogate-model DNN is initialized with initial weights, and an optimizer and loss function are also initialized. Fourth, for each epoch from 1 to E, the training dataset may be shuffled and divided into batches of size B. Fifth, for each batch, the gradients of the DNN may be reset, a forward pass may be performed to compute the predicted output, the loss between the predicted output and the reference output may be computed, backpropagation may be performed to compute gradients with respect to the DNN weights, and the DNN weights may be updated using the optimizer.

Upon completion of the foregoing procedure, the surrogate model is ready for inference on previously unseen well configurations.

### 5.2 Description of FIG. 5A

FIG. 5A illustrates an example process flow 580 for using the surrogate model within the overall FDP optimization workflow. As shown in FIG. 5A, well pool 581 is first generated, for example, according to Algorithm 1 and block 304 of FIG. 3. The process then moves to sampling training dataset 582, where a DOE process is used to generate training cases that respect the relevant spacing constraints. The sampled cases are then simulated and used for training DNN 583. After training, the model becomes DNN ready for prediction 584, and the trained model is then used in optimization of FDP 585 to evaluate alternative well configurations much more rapidly than would be possible using repeated full-physics simulation, for example.

Thus, FIG. 5A makes explicit how the surrogate model fits into the overall workflow: the well pool supplies feasible candidates, wherein the well pool is generated, for example, by the first optimization workflow described with reference to FIG. 3 and Algorithm 1, which clusters the reservoir, evaluates candidate well trajectories, and outputs a pool of candidate well positions that are geologically plausible and satisfy operational constraints. The training dataset provides simulator-derived supervision, the DNN is trained on those data, and the trained model is then deployed in the optimization loop

### 6. Example Computing Implementation

### 6.1 Example Computer Device

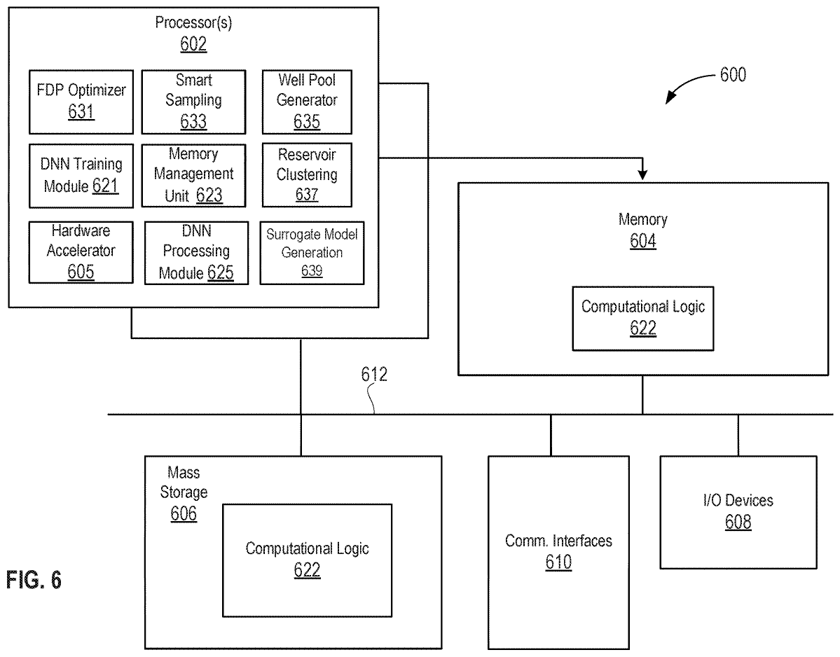

FIG. 6 illustrates an example computer device 600 suitable for implementing the disclosed workflow. In embodiments, computer device 600 may include one or more processors 602, system memory 604, a hardware accelerator 605, mass storage 606, one or more input/output devices 608, one or more communication interfaces 610, and a system bus 612 coupling the foregoing elements.

In embodiments, processors 602 may execute computational logic 622 associated with one or more of the disclosed workflows. By way of example, processors 602 may include or execute DNN training module 621, DNN processing module 625, FDP optimizer 631, smart sampling module 633, well pool generator 635, reservoir clustering module 637, and surrogate model generation module 639. These modules may cooperate to generate the well pool, build a constraint-aware training dataset, train the surrogate model, and use the trained surrogate model during FDP optimization.

In embodiments, hardware accelerator 605 may include a programmable accelerator, such as a field programmable gate array (“FPGA”), a graphics processing unit (“GPU”), or another accelerator suitable for neural-network training and inference. System memory 604 and/or mass storage 606 may store a working copy and/or a persistent copy of computational logic 622, together with operating-system code and other application software.

The example implementation of FIG. 6 is illustrative only. The number, capacity, and configuration of the processors, memory devices, accelerators, and interfaces may vary depending on the implementation.

### 6.2 Example Computer-Readable Storage Medium

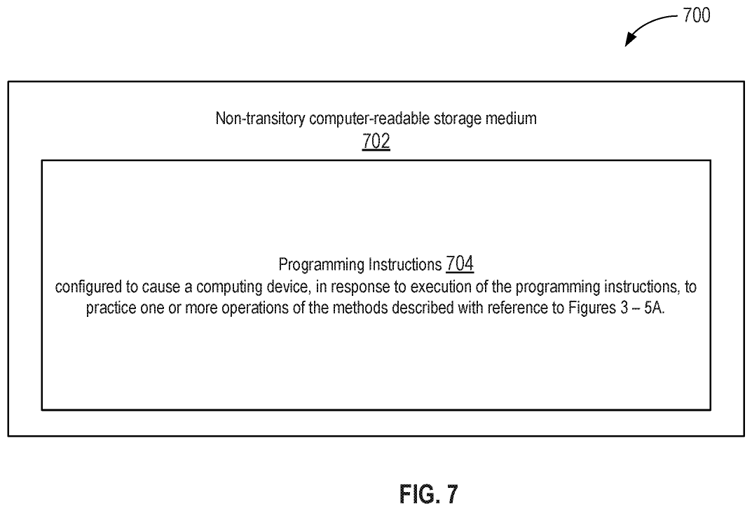

FIG. 7 illustrates an example non-transitory computer-readable storage medium 702 having programming instructions 704 stored thereon. In embodiments, programming instructions 704 are configured, when executed by a computing device, to cause the computing device to perform one or more operations of the methods described herein, including one or more operations associated with the workflows of FIGS. 3, 4, 5, and 5A.

In embodiments, the instructions stored on medium 702 may cause a processor to implement one or more of concatenation block 510, GCN layer 505, GCN layers 523-529, global add pool 530, GRU layer 540, attention layer 550, FFNN 560, well pool 581, sampling training dataset 582, training DNN 583, and optimization of FDP 585. In this manner, the disclosed methods may be embodied not only as a system or apparatus, but also as software stored on a non-transitory computer-readable medium.

### Summary of Surrogate Model Techniques

The above-described surrogate-model section discloses a coherent workflow in which a constraint-aware DOE process is used to generate simulator-based training data, and a staged graph-temporal neural-network architecture is used to learn reservoir response. The architecture is centered on a completion encoder, fusion with petrophysical features, stacked GCN layers, global pooling, temporal modeling of well controls, attention-based selection of relevant temporal information, and a final prediction head. This arrangement is particularly well suited to the well-placement optimization problem because it captures both the spatial interactions among wells and the temporal effect of operational controls within a single surrogate-model framework.

### Examples

In a first example, there may be an apparatus for computing, comprising an input interface configured to receive a base reservoir simulation representative of a geological oil reservoir, a processor configured to: cluster the reservoir into a plurality of sub-regions, AND generate, in a first optimization process, a candidate pool of well positions in the reservoir by screening and pruning a search space of possible well trajectories, each candidate well position being geologically plausible and satisfying one or more operational constraints. The processor is further configured to optimize, in a second optimization process, the candidate pool of well positions to determine an optimized pool of wells that maximizes a dynamic variable of the reservoir. The apparatus further includes an output interface configured to output the optimized pool of wells to a user.

A second example includes the apparatus for computing of the first example, where the optimized pool of well positions specifies a set of producer wells and injector wells that is a subset of the candidate pool of well positions generated in the first optimization process.

A third example includes the apparatus for computing of the first example, where the base reservoir simulation comprises a set of cases with different maps of porosity and permeability that characterize geological uncertainty of the reservoir.

A fourth example includes the apparatus for computing of the first example, where the processor is further configured to, prior to clustering the reservoir, perform a smart sampling sub-process on a plurality of reservoir realizations associated with geological uncertainty.

A fourth example includes the apparatus for computing of the fourth example, where the smart sampling sub-process outputs a subset of K realizations selected from an original set of N realizations based on extracted feature representations of the realizations and clustering of the realizations in a projected feature space, the subset providing probability distributions similar to those of the original set of N realizations.

A sixth example includes the apparatus for computing of the fifth example, where the smart sampling sub-process determines the smallest subset of realizations that provides a similar expected value of a reservoir objective function under geological uncertainty as compared to the full set of realizations.

A seventh example includes the apparatus for computing of the first example, where the clustering includes computing different clusters of the reservoir, each cluster representing a sub-region of the reservoir, using a clustering algorithm.

An eighth example includes the apparatus for computing of the seventh example, where the clustering algorithm is K-means.

A ninth example includes the apparatus for computing of the eighth example, the processor is further configured to post-process the output of K-means clustering to remove salt-and-pepper noise.

A tenth example includes the apparatus for computing of the ninth example, where the post-processing is performed using at least one of: median filters or a pre-trained DNN configured to remove the noise.

An eleventh example includes the apparatus for computing of the first example, where the dynamic variable of the reservoir to be optimized in the second process is net present value (“NPV”).

A twelfth example includes the apparatus for computing of the eleventh example, where NPV is calculated as SUM from t=1 to Nₜ[[Q_{0 to tn}(p,q)*Pₒ−N_{w}*P_{w}]/[(1+λ)^{tn/365}]*[Δtₙ]], where: Qₒ indicates the field-wide oil production rate in stock tank barrels per day (STB/d); N_{w} indicates the total number of wells drilled; Pₒ, P_{w}, and λ respectively indicate: oil price, the cost to drill a well, and the annual discount rate; and tₙ and Δtₙ indicate time and the size of the time step in days.

A thirteenth example includes the apparatus for computing of the first example, where the dynamic variable is recovery factor or oil production.

A fourteenth example includes the apparatus for computing of the first example, the operational constraints include at least one of: a distance between two wells; a maximum number of injectors to drill; a maximum number of producers to drill; a distance between two producer wells; a distance between two injector wells; and a distance between a producer well and an injector well.

A fifteenth example includes the apparatus for computing of the first example, where in the second optimization process, the processor is further configured to apply, within a derivative-free optimization loop, a projection operator to a candidate solution that is infeasible with respect to the operational constraints by replacing the candidate solution with a closest feasible well configuration that satisfies the operational constraints.

A sixteenth example includes the apparatus for computing of the first example, where the processor is further configured, as part of the second optimization process, to train a surrogate model DNN to forecast a production response of the reservoir based on completion-related information, petrophysical information, reservoir cell-coordinate completion data, and time-varying well-control input, and further, to use the trained surrogate model to optimize the pool of wells, wherein the surrogate model includes a spatial encoder configured to encode relationships among wells and/or well completions using the completion-related information and the petrophysical information to generate a spatial representation, a temporal encoder configured to process the time-varying well-control input conditioned on the spatial representation or a derivative thereof, a relevance-weighting mechanism configured to emphasize information most relevant to a predicted production response, and a prediction module configured to output a production forecast.

A seventeenth example includes the apparatus for computing of the sixteenth example, where the graph-based spatial encoder comprises a first graph-convolution layer configured to encode reservoir cell-coordinate completion data to generate a completion embedding, and where the completion embedding is concatenated with the petrophysical information before processing by the one or more additional graph-convolution layers.

An eighteenth example includes the apparatus for computing of the sixteenth example, where the one or more additional graph-convolution layers are configured to output a pooled spatial representation by a global add pooling operation.

A nineteenth example includes the apparatus for computing of the eighteenth example, where the pooled spatial representation is used to initialize a hidden state of the temporal sequence encoder.

A twentieth example includes the apparatus for computing of the sixteenth example, where the temporal encoder comprises a recurrent architecture selected from: a gated recurrent unit (GRU) layer and a long short-term memory (LSTM) layer, or a temporal convolution module configured to receive a sequence of the time-varying well-control input.

A twenty-first example includes the apparatus for computing of the sixteenth example, where the relevance-weighting mechanism comprises an attention mechanism or another feature-selection or gating mechanism configured to emphasize information most relevant to the predicted production response, and where the prediction module is configured to output a time-series forecast of oil production, gas production, water production, injection response, or a combination thereof, at a well level, a field level, or both.

A twenty-second example includes a method of optimizing a set of oil-producing wells to be drilled in a reservoir, the method including receiving a base reservoir simulation representative of a geological oil reservoir, clustering the reservoir into a plurality of sub-regions, and generating, in a first optimization process, a candidate pool of well positions in the reservoir by screening and pruning a search space of possible well trajectories, each candidate well position being geologically plausible and satisfying one or more operational constraints. The method further includes optimizing, in a second optimization process, the candidate pool of well positions to determine an optimized pool of wells that maximizes a dynamic variable of the reservoir, and outputting the optimized pool of wells to a user.

A twenty-second example includes a method of optimizing a set of oil-producing wells to be drilled in a reservoir, the method including receiving a base reservoir simulation representative of a geological oil reservoir, clustering the reservoir into a plurality of sub-regions, and generating, in a first optimization process, a candidate pool of well positions in the reservoir by screening and pruning a search space of possible well trajectories, each candidate well position being geologically plausible and satisfying one or more operational constraints. The method further includes optimizing, in a second optimization process, the candidate pool of well positions to determine an optimized pool of wells that maximizes a dynamic variable of the reservoir, and outputting the optimized pool of wells to a user.

A twenty-third example includes the method of the twenty-second example, where the optimized pool of well positions specifies a set of producer wells and injector wells that is a subset of the candidate pool of well positions generated in the first optimization process.

A twenty-fourth example includes the method of the twenty-second example, where the base reservoir simulation comprises a set of cases with different maps of porosity and permeability that characterize geological uncertainty of the reservoir.

A twenty-fifth example includes the method of the twenty-second example, the method further comprising, prior to clustering the reservoir, performing a smart sampling sub-process on a plurality of reservoir realizations associated with geological uncertainty.

A twenty-sixth example includes the method of the twenty-fifth example, where the smart sampling sub-process outputs a subset of K realizations selected from an original set of N realizations based on extracted feature representations of the realizations and clustering of the realizations in a projected feature space, the subset providing probability distributions similar to those of the original set of N realizations.

A twenty-seventh example includes the method of the twenty-sixth example, where the smart sampling sub-process determines the smallest subset of realizations that provides a similar expected value of a reservoir objective function under geological uncertainty as compared to the full set of realizations.

A twenty-eighth example includes the method of the twenty-second example, where the clustering includes computing different clusters of the reservoir, each cluster representing a sub-region of the reservoir, using a clustering algorithm. Or, additionally, where the clustering algorithm is K-means.

A twenty-ninth example includes the method of the twenty-eighth example, further comprising post-processing the output of the K-means clustering to remove salt-and-pepper noise.

A thirtieth example includes the method of the twenty-ninth example, where the post-processing includes using at least one of: median filters or a pre-trained DNN configured to remove the noise.

A thirty-first example includes the method of the twenty-second example, where the dynamic variable of the reservoir to be optimized in the second process is net present value (“NPV”).

A thirty-second example includes the method of the thirty-first example, where the NPV is calculated as: SUM from t=1 to Nₜ[Q_{0 to tn}(p,q)*Pₒ−N_{w}*P_{w}]/[(1+λ)^{tn/365}]*[Δtₙ]],

where: Qₒ indicates the field-wide oil production rate in stock tank barrels per day (STB/d); N_{w} indicates the total number of wells drilled; Pₒ, P_{w}, and λ respectively indicate: oil price, the cost to drill a well, and the annual discount rate; and tₙ and Δtₙ indicate time and the size of the time step in days.

A thirty-third example includes the method of the twenty-second example, where the dynamic variable is recovery factor or oil production.

A thirty-second example includes the method of the twenty-second example, where the operational constraints include at least one of: a distance between two wells; a maximum number of injectors to drill; a maximum number of producers to drill; a distance between two producer wells; a distance between two injector wells; and a distance between a producer well and an injector well.

A thirty-third example includes the method of the twenty-second example, further comprising, in the second optimization process, applying, within a derivative-free optimization loop, a projection operator to a candidate solution that is infeasible with respect to the operational constraints by replacing the candidate solution with a closest feasible well configuration that satisfies the operational constraints.

A thirty-fourth example includes the method of the twenty-second example, further comprising, as part of the second optimization process: training a DNN surrogate model to forecast a production response of the reservoir based on completion-related information, petrophysical information, reservoir cell-coordinate completion data, and time-varying well-control input; and using the trained DNN surrogate model to optimize the pool of wells, wherein the surrogate model includes a spatial encoder configured to encode relationships among wells and/or well completions using the completion-related information and the petrophysical information to generate a spatial representation, a temporal encoder configured to process the time-varying well-control input conditioned on the spatial representation or a derivative thereof, a relevance-weighting mechanism configured to emphasize information most relevant to a predicted production response, and a prediction module configured to output a production forecast.

A thirty-fifth example includes the method of the thirty-fourth example, where the graph-based spatial encoder comprises a first graph-convolution layer configured to encode reservoir cell-coordinate completion data to generate a completion embedding, and wherein the completion embedding is concatenated with the petrophysical information before processing by the one or more additional graph-convolution layers.

A thirty-sixth example includes the method of the thirty-fifth example, where the one or more additional graph-convolution layers output a pooled spatial representation by a global add pooling operation.

A thirty-seventh example includes the method of the thirty-sixth example, where the pooled spatial representation is used to initialize a hidden state of the temporal sequence encoder.

A thirty-eighth example includes the method of the thirty-fifth example, where the temporal encoder comprises a recurrent architecture selected from a gated recurrent unit (GRU) layer and a long short-term memory (LSTM) layer, or a temporal convolution module configured to receive a sequence of the time-varying well-control input.

A thirty-ninth example includes the method of the thirty-fifth example, where the relevance-weighting mechanism comprises an attention mechanism or another feature-selection or gating mechanism configured to emphasize information most relevant to the predicted production response, and wherein the prediction module is configured to output a time-series forecast of oil production, gas production, water production, injection response, or a combination thereof, at a well level, a field level, or both.

Although particular embodiments, aspects, and features have been described and illustrated, it should be noted that the invention described herein is not limited to only those embodiments, aspects, and features. It should readily be appreciated that modifications may be made by persons skilled in the art. The present application contemplates any and all modifications within the spirit and scope of the underlying embodiments described and claimed herein, and all such embodiments are within the scope and spirit of the present disclosure.

### REFERENCES CITED IN THE DESCRIPTION

[1] R. H. Chan, C.-W. Ho, and M. Nikolova. Salt-and-pepper noise removal by median-type noise detectors and detail-preserving regularization. IEEE Transactions on image processing, 14(10):1479-1485, 2005.
[2] J. Christensen, E. Stenby, and A. Skauge. Review of wag field experience. society of petroleum engineers, 2001.
[3] P. Dufoss'e and N. Hansen. Augmented Iagrangian, penalty techniques and surrogate modeling for constrained optimization with cma-es. In Proceedings of the Genetic and Evolutionary Computation Conference, pages 519-527, 2021.
[4] D. Erbas, M. Dunning, T. M. Nash, D. Cox, J. A. Stripe, and E. Duncan. Magnus wag pattern optimization through data integration. In SPE Improved Oil Recovery Conference?, pages SPE-169167. SPE, 2014.
[5] F. Forouzanfar, G. Li, and A. C. Reynolds. A two-stage well placement optimization method based on adjoint gradient. In SPE Annual Technical Conference and Exhibition?, pages SPE-135304. SPE, 2010.
[6] N. Hansen, S. D. M\ddot{ } uller, and P. Koumoutsakos. Reducing the time complexity of the derandomized evolution strategy with covariance matrix adaptation (cma-es). Evolutionary computation, 11(1):1-18, 2003.
[7] J. D. Head and M. C. Zerner. A broyden-fletcher-goldfarb-shanno optimization procedure for molecular geometries. Chemical physics letters, 122(3):264-270, 1985.
[8] O. J. Isebor, D. E. Ciaurri, and L. J. Durlofsky. Generalized field-development optimization with derivative-free procedures. Spe Journal, 19(05):891-908, 2014.
[9] Y. D. Kim and L. J. Durlofsky. Convolutional-recurrent neural network proxy for robust optimization and closed-loop reservoir management. Computational Geosciences, 27(2):179-202, 2023.
[10] K. Krishna and M. N. Murty. Genetic k-means algorithm. IEEE Transactions on Systems, Man, and Cybernetics, Part B (Cybernetics), 29(3):433-439, 1999.
[11] R. Lu, F. Forouzanfar, and A. C. Reynolds. Bi-objective optimization of well placement and controls using stosag. In SPE Reservoir Simulation Conference?, page D012S014R006. SPE, 2017.
[12] A. Miyagi, Y. Akimoto, and H. Yamamoto. Well placement optimization for carbon dioxide capture and storage via cma-es with mixed integer support. In Proceedings of the Genetic and Evolutionary Computation Conference Companion, pages 1696-1703, 2018.
[13] J. Navr'atil, A. King, J. Rios, G. Kollias, R. Torrado, and A. Codas. Accelerating physics-based simulations using end-to-end neural network proxies: An application in oil reservoir modeling. Frontiers in big Data, 2:33, 2019.
[14] M. Panda, J. G. Ambrose, G. Beuhler, and P. McGuire. Optimized eor design for the eileen west end area, greater prudhoe bay. SPE Reservoir Evaluation & Engineering, 12(01):25-32, 2009.
[15] S. D. Rahmawati, C. H. Whitson, and B. Foss. A mixed-integer non-linear problem formulation for miscible wag injection. Journal of Petroleum Science and Engineering, 109:164-176, 2013.
[16] M. Sarabian, P. Ruiz Mataran, and R. Rodriguez Torrado. Finite pinn net: Physics-informed deep convolutional neural networks for learning 3d transient darcy flows in heterogeneous porous media. Bulletin of the American Physical Society, 2022.
[17] R. R. Torrado, D. E. Ciaurri, U. T. Mello, and S. E. Droz. Fast reservoir performance evaluation under uncertainty: opening new opportunities. In SPE Annual Technical Conference and Exhibition, page D011 S007R005. SPE, 2013.
[18] R. R. Torrado, G. D. Paola, A. F. Perez, A. Fuenmayor, M. S. De Azevedo, and S. Embid. Optimize a wag field development plan, use case of carbonate ultra-deep water reservoir. In SPE Europec featured at EAGE Conference and Exhibition, pages SPE-174344. SPE, 2015.
[19] D. Yang, Q. Zhang, H. Cui, H. Feng, and L. Li. Optimization of multivariate production-injection system for water-alternating-gas miscible flooding in pubei oil field. In SPE Western Regional Meeting, pages SPE-62856. SPE, 2000.
[20] S. Yu, J. Ma, and W. Wang. Deep learning for denoising. Geophysics, 84(6): V333-V350, 2019.

What is claimed:

1. An apparatus for computing, comprising:
an input interface configured to receive:
a base reservoir simulation representative of a geological oil reservoir;
a processor configured to:
cluster the reservoir into a plurality of sub-regions;
generate, in a first optimization process, a candidate pool of well positions in the reservoir by screening and pruning a search space of possible well trajectories, each candidate well position being geologically plausible and satisfying one or more operational constraints; and
optimize, in a second optimization process, the candidate pool of well positions to determine an optimized pool of wells that maximizes a dynamic variable of the reservoir; and
an output interface configured to output the optimized pool of wells to a user.

2. The apparatus for computing of claim 1, wherein at least one of:
the optimized pool of well positions specifies a set of producer wells and injector wells that is a subset of the candidate pool of well positions generated in the first optimization process;
the base reservoir simulation comprises a set of cases with different maps of porosity and permeability that characterize geological uncertainty of the reservoir; and
the processor is further configured, prior to clustering the reservoir, to perform a smart sampling sub-process on a plurality of reservoir realizations associated with geological uncertainty.

3. The apparatus for computing of claim 4, wherein:
the processor is further configured, prior to clustering the reservoir, to perform a smart sampling sub-process on a plurality of reservoir realizations associated with geological uncertainty, and
the smart sampling sub-process outputs a subset of K realizations selected from an original set of N realizations based on extracted feature representations of the realizations and clustering of the realizations in a projected feature space, the subset providing probability distributions similar to those of the original set of N realizations.

4. The apparatus for computing of claim 3, wherein the smart sampling sub-process determines the smallest subset of realizations that provides a similar expected value of a reservoir objective function under geological uncertainty as compared to the full set of realizations.

5. The apparatus for computing of claim 1, wherein the processor is further configured to post-process the output of K-means clustering to remove salt-and-pepper noise.

6. The apparatus for computing of claim 1, wherein the operational constraints include at least one of:
a distance between two wells; a maximum number of injectors to drill; a maximum number of producers to drill; a distance between two producer wells; a distance between two injector wells; and a distance between a producer well and an injector well.

7. The apparatus for computing of claim 1, wherein, in the second optimization process, the processor is further configured to apply, within a derivative-free optimization loop, a projection operator to a candidate solution that is infeasible with respect to the operational constraints by replacing the candidate solution with a closest feasible well configuration that satisfies the operational constraints.

8. The apparatus for computing of claim 1, wherein the processor is further configured, as part of the second optimization process, to:
train a surrogate model DNN to forecast a production response of the reservoir based on completion-related information, petrophysical information, reservoir cell-coordinate completion data, and time-varying well-control input; and
use the trained surrogate model to optimize the pool of wells, wherein the surrogate model includes a spatial encoder configured to encode relationships among wells and/or well completions using the completion-related information and the petrophysical information to generate a spatial representation, a temporal encoder configured to process the time-varying well-control input conditioned on the spatial representation or a derivative thereof, a relevance-weighting mechanism configured to emphasize information most relevant to a predicted production response, and a prediction module configured to output a production forecast.

9. The apparatus for computing of claim 8, wherein the graph-based spatial encoder comprises a first graph-convolution layer configured to encode reservoir cell-coordinate completion data to generate a completion embedding, and wherein the completion embedding is concatenated with the petrophysical information before processing by the one or more additional graph-convolution layers.

10. The apparatus for computing of claim 8, wherein the one or more additional graph-convolution layers are configured to output a pooled spatial representation by a global add pooling operation.

11. The apparatus for computing of claim 10, wherein the pooled spatial representation is used to initialize a hidden state of the temporal sequence encoder.

12. The apparatus for computing of claim 8, wherein the temporal encoder comprises a recurrent architecture selected from a gated recurrent unit (GRU) layer and a long short-term memory (LSTM) layer, or a temporal convolution module configured to receive a sequence of the time-varying well-control input.

13. The apparatus for computing of claim 12, wherein the relevance-weighting mechanism comprises an attention mechanism or another feature-selection or gating mechanism configured to emphasize information most relevant to the predicted production response, and wherein the prediction module is configured to output a time-series forecast of oil production, gas production, water production, injection response, or a combination thereof, at a well level, a field level, or both.

14. A method of optimizing a set of oil-producing wells to be drilled in a reservoir, comprising:
receiving a base reservoir simulation representative of a geological oil reservoir;
clustering the reservoir into a plurality of sub-regions;
generating, in a first optimization process, a candidate pool of well positions in the reservoir by screening and pruning a search space of possible well trajectories, each candidate well position being geologically plausible and satisfying one or more operational constraints; and
optimizing, in a second optimization process, the candidate pool of well positions to determine an optimized pool of wells that maximizes a dynamic variable of the reservoir; and
outputting the optimized pool of wells to a user.

15. The method of claim 14, further comprising, prior to clustering the reservoir, performing a smart sampling sub-process on a plurality of reservoir realizations associated with geological uncertainty.

16. The method of claim 15, wherein the smart sampling sub-process outputs a subset of K realizations selected from an original set of N realizations based on extracted feature representations of the realizations and clustering of the realizations in a projected feature space, the subset providing probability distributions similar to those of the original set of N realizations.

17. The method of claim 16, wherein the smart sampling sub-process determines the smallest subset of realizations that provides a similar expected value of a reservoir objective function under geological uncertainty as compared to the full set of realizations.

18. The method of claim 14, wherein at least one of:
the clustering includes computing different clusters of the reservoir, each cluster representing a sub-region of the reservoir, using a clustering algorithm, or
the operational constraints include at least one of:
a distance between two wells; a maximum number of injectors to drill; a maximum number of producers to drill; a distance between two producer wells; a distance between two injector wells; and a distance between a producer well and an injector well.

19. The method of claim 14, further comprising, as part of the second optimization process:
training a DNN surrogate model to forecast a production response of the reservoir based on completion-related information, petrophysical information, reservoir cell-coordinate completion data, and time-varying well-control input; and
using the trained DNN surrogate model to optimize the pool of wells, wherein the surrogate model includes a spatial encoder configured to encode relationships among wells and/or well completions using the completion-related information and the petrophysical information to generate a spatial representation, a temporal encoder configured to process the time-varying well-control input conditioned on the spatial representation or a derivative thereof, a relevance-weighting mechanism configured to emphasize information most relevant to a predicted production response, and a prediction module configured to output a production forecast.

20. The method of claim 19, wherein, at least one of:
the graph-based spatial encoder comprises a first graph-convolution layer configured to encode reservoir cell-coordinate completion data to generate a completion embedding, and the completion embedding is concatenated with the petrophysical information before processing by the one or more additional graph-convolution layers,
or
the one or more additional graph-convolution layers output a pooled spatial representation by a global add pooling operation.
